(19) United States
(12) Patent Application Publication
(10) Pub. No.: US 2011/0079775 A1
(43) Pub. Date: Apr. 7, 2011

(54) Solution Processable Organic Semiconductors

(76) Inventor: Peiwang Zhu, Woodbury, MN (US)

(21) Appl. No.: 12/994,898

(22) PCT Filed: Apr. 28, 2009
(86) PCT No.: PCT/US09/41904

§ 371 Date: Nov. 29, 2010

Related U.S. Application Data
(62) Division of application No. 61/074,002, filed on Jun. 19, 2008.

(51) Int. Cl. H01L 51/05; H01L 51/40; C07F 7/08; H01B 1/12

(52) U.S. Cl. 257/40; 438/99; 556/403; 556/431; 252/500; 257/E51.005; 257/E51.003

(57) ABSTRACT

Semiconductor material, compositions containing the semiconductor material, semiconductor devices containing the semiconductor material, and methods of making semiconductor devices containing the semiconductor material are described. More specifically, the semiconductor material is a small molecule semiconductor that is an anthracene-based compound (i.e., anthracene derivative) that is substituted with two silylethynyl groups as well as two electron donating groups.

### TECHNICAL FIELD

Semiconductor material, compositions containing the semiconductor material, semiconductor devices containing the semiconductor material, and methods of making semiconductor devices containing the semiconductor material are described.

### BACKGROUND

Traditionally, inorganic materials have dominated the semiconductor industry. For example, silicon arsenide and gallium arsenide have been used as semiconductor materials, silicon dioxide has been used as an insulator material, and metals such as aluminum and copper have been used as electrode materials. In recent years, however, there has been an increasing research effort aimed at using organic materials rather than the traditional inorganic materials in semiconductor devices. Among other benefits, the use of organic materials may enable lower cost manufacturing of electronic devices, may enable large area applications, and may enable the use of flexible circuit supports for display backplanes or integrated circuits.

A variety of organic semiconductor materials have been considered, the most common being fused aromatic ring compounds as exemplified by tetracene, pentacene, bis(acenyl)acetylene, and acene-thiophenes; oligomeric materials containing thiophene or fluorene units; and polymeric materials such as regioregular poly(3-alkylthiophene). At least some of these organic semiconductor materials have performance characteristics such as charge-carrier mobility, on/off current ratios, and sub-threshold voltages that are comparable or superior to those of amorphous silicon-based devices. These materials usually need to be vapor deposited since they are not very soluble in most solvents.

Because of its good electronic performance characteristics, pentacene is often the organic semiconductor of choice. However, pentacene can be difficult to synthesize and purify. Because of the limited solubility of pentacene in many common solvents, semiconductor layers containing pentacene typically cannot be formed using solvent-based deposition techniques. As an additional complication for solvent-based deposition techniques, pentacene tends to oxidize or undergo dimerization reactions in many solutions. Once deposited in a semiconductor layer, pentacene can oxidize over time. This can lead to reduced performance or complete failure of the semiconductor device that contains the oxidized pentacene.

### SUMMARY

Semiconductor material, compositions containing the semiconductor material, semiconductor devices containing the semiconductor material, and methods of making semiconductor devices containing the semiconductor material are described. More specifically, the semiconductor material is a small molecule semiconductor that is an anthracene-based compound (i.e., anthracene derivative) that is substituted with two silylethynyl groups as well as two electron donating groups.

In a first aspect, a small molecule semiconductor of Formula (I) is provided.

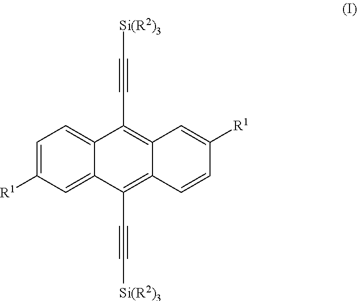

In this formula, each R¹ is independently a phenyl or naphthyl. The phenyl or naphthyl group can be unsubtituted or substituted with one or more groups selected from halogen, hydroxyl, amino, alkyl, alkenyl, alkoxy, acyloxy, heteroaryl, heteroalkyl, or heteroaralkyl. Each R² group is independently selected from alkyl, alkenyl, alkoxy, aryl, heteroaryl, aralkyl, heteroalkyl, heteroaralkyl, or hydroxyalkyl.

In a second aspect, a composition is provided that includes (a) a small molecule semiconductor, and (b) an organic solvent. The small molecule semiconductor is of Formula (I) as described above. In some embodiments, the composition further includes an insulating polymer.

In a third aspect, a semiconductor device is provided. The semiconductor device contains a semiconductor layer that includes a small molecule semiconductor of Formula (I). In some embodiments, the semiconductor layer further includes an insulating polymer.

In a fourth aspect, a method of making a semiconductor device is provided. The method includes providing a semiconductor layer that contains a small molecule semiconductor of Formula (I). In some embodiments, the semiconductor layer further includes an insulating polymer.

The above summary of the present invention is not intended to describe each embodiment or every implementation of the present invention. The Figures, Detailed Description, and Examples that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 schematically illustrates a first exemplary thin film transistor.

FIG. 2 schematically illustrates a second exemplary thin film transistor.

FIG. 3 schematically illustrates a third exemplary thin film transistor.

FIG. 4 schematically illustrates a fourth exemplary thin film transistor.

FIG. 5 schematically illustrates a fifth exemplary thin film transistor.

FIG. 6 schematically illustrates a sixth exemplary thin film transistor.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION OF THE INVENTION

Small molecule semiconductors are provided that can be included in a semiconductor layer within a semiconductor device such as, for example, a thin film transistor. The small molecule semiconductors, which are usually p-type semiconductors, are anthracene derivatives and have two silylethynyl groups as well as two electron donating groups. The electron donating groups are selected from a phenyl or naphthyl group and can be unsubstituted or substituted with one or more substituents such as halo, hydroxyl, amino, alkyl, alkenyl, alkoxy, acyloxy, heteroaryl, heteroalkyl, or heteroaralkyl groups.

As used herein, the terms “a”, “an”, and “the” are used interchangeably with “at least one” to mean one or more of the elements being described.

The term “alkyl” refers to a monovalent group that is a radical of an alkane, a saturated hydrocarbon. The alkyl can be linear, branched, cyclic, or combinations thereof and typically contains 1 to 30 carbon atoms. In some embodiments, the alkyl group contains 1 to 20 carbon atoms, 1 to 14 carbon atoms, 1 to 10 carbon atoms, 4 to 10 carbon atoms, 4 to 8 carbon atoms, 1 to 8 carbon atoms, 1 to 6 carbon atoms, or 1 to 4 carbon atoms. Examples of alkyl groups include, but are not limited to, methyl, ethyl, n-propyl, isopropyl, n-butyl, tert-butyl, iso-butyl, n-pentyl, n-hexyl, cyclohexyl, cyclopentyl, cyclobutyl, cyclopropyl, n-heptyl, n-octyl, and ethylhexyl.

The term “alkoxy” refers to a monovalent group of formula —OR where R is an alkyl group. Examples include methoxy, ethoxy, propoxy, butoxy, and the like.

The term “alkenyl” refers to a monovalent group that is a radical of an alkene, a hydrocarbon with at least one carbon-carbon double bond. The alkenyl can be linear, branched, cyclic, or combinations thereof and typically contains 2 to 30 carbon atoms. In some embodiments, the alkenyl contains 2 to 20 carbon atoms, 2 to 14 carbon atoms, 2 to 10 carbon atoms, 4 to 10 carbon atoms, 4 to 8 carbon atoms, 2 to 8 carbon atoms, 2 to 6 carbon atoms, or 2 to 4 carbon atoms. Exemplary alkenyl groups include ethenyl, n-propenyl (i.e., allyl), iso-propenyl, and n-butenyl.

The term “amino” refers to a monovalent group of formula —N(R^{b})₂ where each R^{b} is independently hydrogen, alkyl, heteroalkyl, aryl, or aralkyl.

The term “aryl” refers to a monovalent group that is a radical of an aromatic carbocyclic compound. The term “carbocyclic” refers to a ring structure in which all the ring atoms are carbon. The aryl can have one aromatic ring or can include up to 5 carbocyclic ring structures that are connected to or fused to the aromatic ring. The other ring structures can be aromatic, non-aromatic, or combinations thereof. Examples of aryl groups include, but are not limited to, phenyl, biphenyl, terphenyl, anthryl, naphthyl, acenaphthyl, anthraquinonyl, phenanthryl, anthracenyl, pyrenyl, perylenyl, and fluorenyl.

The term “aralkyl” refers to a monovalent group that is a radical of the compound R—Ar where Ar is an aromatic carbocyclic group and R is an alkyl group. The aralkyl is often an alkyl substituted with an aryl group.

The term “acyloxy” refers to a monovalent group of formula —O(CO)R^{c} where (CO) denotes a carbonyl group and R^{c} is alkyl, heteroalkyl, aryl, or aralkyl.

The term “halo” refers to a halogen group (i.e., —F, —Cl, —Br, or —I).

The term “hydroxyalkyl” refers to an alkyl substituted with at least one hydroxyl group.

The term “heteroalkyl” refers to an alkyl having one or more —CH₂— groups replaced with a thio, oxy, a group of formula —NR^{b}— where R^{b} is hydrogen, alkyl, heteroalkyl, aralkyl, or aryl, or a group of formula —SiR₂— where R is an alkyl. The heteroalkyl can be linear, branched, cyclic, or combinations thereof and can include up to 30 carbon atoms and up to 20 heteroatoms. In some embodiments, the heteroalkyl includes up to 25 carbon atoms, up to 20 carbon atoms, up to 15 carbon atoms, or up to 10 carbon atoms. Thioalkyl groups and alkoxy groups are subsets of heteroalkyl groups. Other heteroalkyl groups have a —CH₂— group on both sides of the thio, oxy, —NR^{b}—, or —SiR₂— group.

The term “heteroaryl” refers to a monovalent radical having a five to seven member aromatic ring that includes one or more heteroatoms independently selected from S, O, N, or combinations thereof in the ring. Such a heteroaryl ring can be connected to or fused to up to five ring structures that are aromatic, aliphatic, or combinations thereof. Examples of heteroaryl groups include, but are not limited to, furanyl, thiophenyl, pyrrolyl, imidazolyl, pyrazolyl, triazolyl, tetrazolyl, thiazolyl, oxazolyl, isoxazolyl, oxadiazolyl, thiadiazolyl, isothiazolyl, pyridinyl, pyridazinyl, pyrazinyl, pyrimidinyl, quinolinyl, isoquinolinyl, benzofuranyl, benzothiophenyl, indolyl, carbazoyl, benzoxazolyl, benzothiazolyl, benzimidazolyl, cinnolinyl, quinazolinyl, quinoxalinyl, phthalazinyl, benzothiadiazolyl, benzotriazinyl, phenazinyl, phenanthridinyl, acridinyl, and indazolyl, and the like.

The term “heteroaralkyl” refers to an alkyl substituted with a heteroaryl.

The term “hydroxyl” refers to a group of formula —OH.

The term “silylethynyl” refers to a monovalent group of formula —C≡C—Si(R^{a})₃ where R^{a} is independently selected from alkyl, alkoxy, alkenyl, heteroalkyl, hydroxyalkyl, aryl, aralkyl, heteroaryl, or heteroaralkyl. These groups are sometimes referred to as silanylethynyl groups.

The term “trialkylsilyl” refers to a monovalent group of formula —SiR₃ where each R is an alkyl.

The phrase “in the range of” includes the endpoints of the range and all the numbers between the endpoints. For example, the phrase in the range of 1 to 10 includes 1, 10, and all numbers between 1 and 10. Further, unless specifically stated otherwise, any recitation of a range that is not specifically called a range includes the endpoint and all number between the endpoints.

Unless otherwise indicated, all numbers expressing feature sizes, amounts, and physical properties used in the specification and claims are to be understood as being modified in all instances by the term “about.” Accordingly, unless indicated to the contrary, the numbers set forth are approximations that can vary depending upon the desired properties using the teachings disclosed herein.

In a first aspect, a small molecule semiconductor is provided. As used herein, the term “small molecule” in reference to the semiconductor material means that the semiconductor is not a polymeric material. The small molecule semiconductor is an anthracene derivative that has two silylethynyl as well as two electron donating groups. The small molecule semiconductor is of Formula (I).

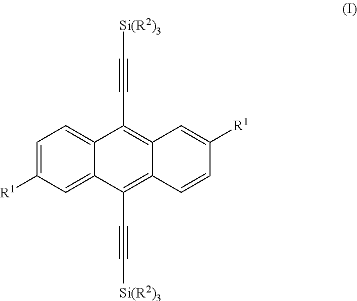

In this formula, each R¹ is independently selected from a phenyl or naphthyl, where the phenyl or naphthyl group can be unsubtituted or substituted with one or more substituents. Suitable substituents for the phenyl or naphthyl group include halo, hydroxyl, amino, alkyl, alkenyl, alkoxy, acyloxy, heteroaryl, heteroalkyl, or heteroaralkyl groups. Each R² group is independently selected from alkyl, alkenyl, alkoxy, aryl, heteroaryl, aralkyl, heteroalkyl, heteroaralkyl, or hydroxyalkyl.

Suitable alkyl, alkenyl, alkoxy, acyloxy, and heteroalkyl substituents for a phenyl or naphthyl R¹ group can be linear, cyclic, or a combination thereof and usually contains up to 10 carbon atoms, up to 8 carbon atoms, up to 6 carbon atoms, or up to 4 carbon atoms. Heteroalkyl substituents for a phenyl or naphthyl R¹ group often have an oxy group as the heteroatom. Suitable heteroaryl substituents often have a 5 or 6 membered saturated or unsaturated heterocyclic ring that includes 1 or 2 heteroatoms. Exemplary heteroaralkyl substiutents have an alkyl with up to 10 carbon atoms that is substituted with a 5 or 6 membered heteroaryl having 1 or 2 heteroatoms. Suitable amino groups can be primary amino groups, secondary amino groups, or tertiary amino groups.

In some embodiments, the R¹ group is a phenyl substituted with a single R³ group or a naphthyl group substituted with a single R³ group as shown in Formulas (II) to (IV) where R³ is selected from hydrogen, halo, hydroxyl, amino, alkyl, alkenyl, alkoxy, acyloxy, heteroaryl, heteroalkyl, or heteroaralkyl. The R³ group can be on any carbon atom of the phenyl or naphthyl group that is not directly attached to the anthracene portion of the small molecule.

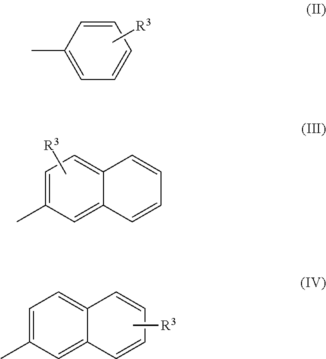

In some more specific embodiments, the R¹ group in Formula (I) can be of Formula (V) or (VI)

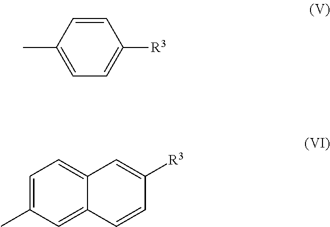

In some even more specific embodiments, R³ in any of Formulas (II) to (VI) is an alkoxy group having up to 10 carbon atoms, up to 6 carbon atoms, up to 4 carbon atoms, up to 3 carbon atoms, or 1 carbon atom.

Each of the silylethynyl group included in the small molecule semiconductor of Formula (I) is of formula —C≡C—Si—(R²)₃ where each R² is independently alkyl, alkoxy, alkenyl, aryl, heteroaryl, aralkyl, heteroalkyl, heteroaralkyl, or hydroxyalkyl. Exemplary alkyl, alkoxy, alkenyl, heteroalkyl, and hydroxyalkyl groups can be linear, branched, cyclic, or a combination thereof and usually have up to 10 carbon atoms, up to 8 carbon atoms, up to 6 carbon atoms, or up to 4 carbon atoms. An exemplary aryl group is phenyl and an exemplary aralkyl is an alkyl having up to 10 carbon atoms that is substituted with a phenyl group. Exemplary heteroaryl groups often have a 5 or 6 membered unsaturated, heterocyclic ring that includes 1 or 2 heteroatoms. Exemplary heteroaralkyl groups have an alkyl having up to 10 carbon atoms that is substituted with a 5 or 6 membered heteroaryl having 1 or 2 heteroatoms.

In some exemplary silylethynyl groups, each R² is an alkyl that is linear or branched and that has up to 10 carbon atoms, up to 8 carbon atoms, up to 6 carbon atoms, or up to 4 carbon atoms. That is, the silylethynyl group is a trialkylsilylethynyl group. Each R² group can be, for example, isopropyl, n-propyl, n-butyl, n-pentyl, or n-hexyl. For example, the silylethynyl group can be triisopropylsilylethynyl where each R² is isopropyl.

In other exemplary silylethynyl groups, each R² group is an alkyl group but at least one of the alkyl groups is cyclic. All or only a portion of the carbon atoms in the alkyl group can be included in a carbocyclic ring. Some exemplary alkyl groups have 3 to 6 carbon atoms and all of the carbon atoms are part of the carbocyclic ring. Other exemplary alkyl groups have a linear or branched portion having up to 10 carbon atoms attached to a cyclic portion having up to 6 carbon atoms. Either the non-cyclic portion (i.e., linear or branched portion) or the cyclic portion of the alkyl group can be attached to the silicon of the silylethynyl group. Examples of cyclic alkyl groups include, but are not limited to cylcopropyl, cyclobutyl, cyclopentyl, cyclohexyl, 2,2,3,3-tetramethylcyclopropyl, 2,3-dimethylcyclopropyl, cyclobutylmethylene, and cyclopropylmethylene.

In still other exemplary silylethynyl groups, at least one of the R² groups is an alkenyl group and any R² group that is not an alkenyl group is an alkyl group. That is, the silylethynyl group can be a trialkenylsilylethynyl, alkyldialkenylsilylethynyl, or dialkylalkenylsilylethynyl. The alkenyl and alkyl groups can each be linear or branched and can have up to 10 carbon atoms, up to 8 carbon atoms, up to 6 carbon atoms, or up to 4 carbon atoms. For example, each of the alkenyl groups and any alkyl groups can have either 3 or 4 carbon atoms. Exemplary alkenyl groups include, but are not limited to, allyl, isopropenyl, 2-but-1-enyl, and 3-but-1-enyl.

The small molecule semiconductor of Formula (I) can be prepared by any known synthesis method. For example, the semiconductor can be prepared as shown in Reaction Scheme A.

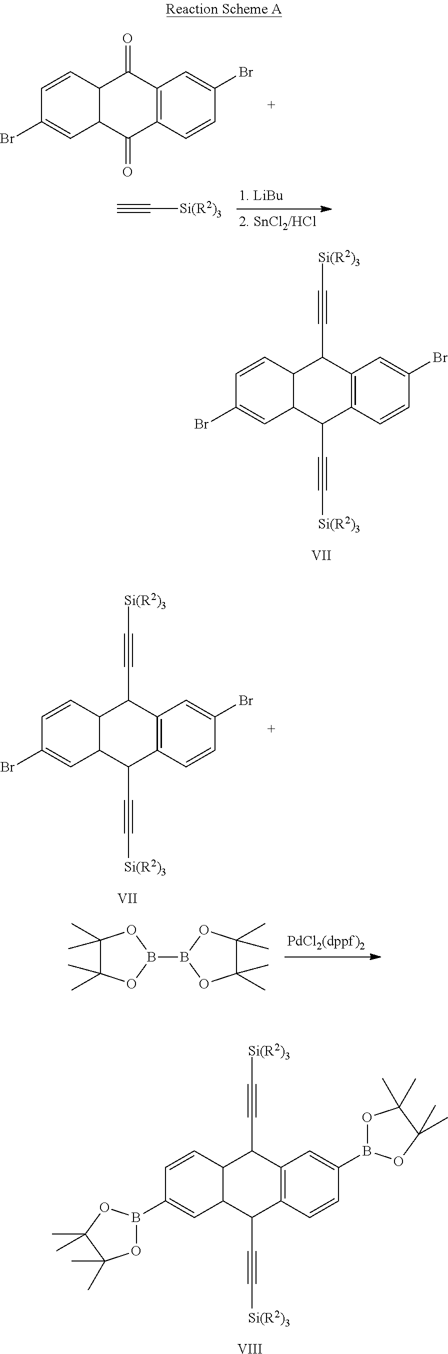

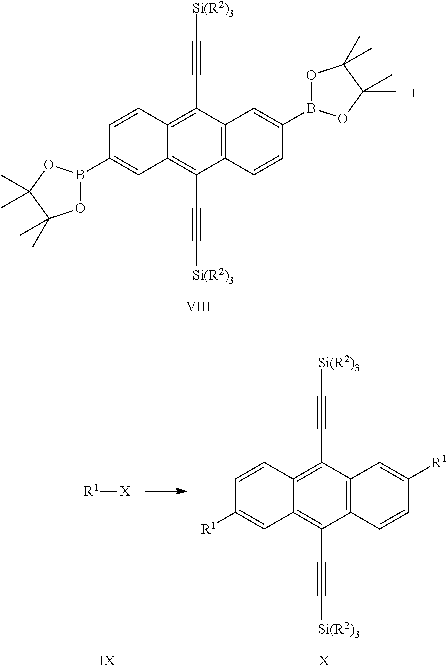

Initially, a silylacetylene compound of formula H—C≡CH—Si(R²)₃ can be treated with butyl lithium to form a lithiated version Li—C≡CH—Si(R²)₃ of the silylacetylene compound. Various silylacetylene compounds are commercially available. For example, (trimethylsilyl)acetylene, (triethylsilyl)acetylene, (triisopropylsilyl)acetylene, and (tert-butyldimethylsilyl)acetylene are available from GFS Chemicals (Columbus, Ohio). (Dimethylphenylsilyl)acetylene, (methyldiphenylsilyl)acetylene, and (triphenylsilyl)acetylene are available from Sigma Aldrich (Milwaukee, Wis.).

The lithiated version of the silylacetylene compound can then be reacted with a 2,6-dihaloanthraquinone such as 2,6-dibromoanthraquinone. The resulting diol intermediate can then be treated with a reducing agent such as stannous chloride to form the 2,6-dihalo-9,10-bis(silylethynyl)anthracene of Formula (VII). 2,6-dibromoanthraquinone can be prepared from 2,6-diaminoanthraquinone from Sigma Aldrich (Milwaukee, Wis.) using the procedure described by Ito et al., Angew. Chem. Int. Ed., 42, 1159-1162 (2003). It can be further recrystallized from N,N-dimethylformamide (DMF).

The 2,6-dihalo-9,10-bis(silylethynyl)anthracene of Formula (VII) can then be reacted with a dioxaborolane such as bis(pinacolato)diboron to form a compound of Formula (VIII) that has two dioxaborolane groups such as tetramethyldioxaborolane. The compound of Formula (VIII) subsequently can be reacted with a halogenated benzene or halogenated naphthalene compound of Formula (IX) to form the semiconductor compound of Formula (X).

Suitable halogentated benzene or halogentated naphthalene compounds of Formula (IX) are commercially available. For example, 4-bromoanisole, 4-bromobenzene, 4-bromo-N,N-dimethylaniline, 4-bromodiphenyl ether, 4-bromotoluene, 4-bromostyrene, 1-bromo-4-ethylbenzene, 4-bromophenol, 4-bromoaniline, 4-bromo-N,N-diethylaniline, 1-bromo-4-cyclohexylbenzene, 1-bromo-4-butoxybenzene, 1-bromo-4-N-octylbenzene, 2-bromonaphthalene, 2-bromo-6-methoxynaphthalene, 6-bromo-2-naphthalenol, 2-bromo-6-butoxynaphthalene, 2-bromo-6-ethoxynaphthalene, 1-bromonaphthalene et. al. are available from Alfa Aesar (Ward Hill, Mass.).

The small molecule semiconductors of Formula (I) are usually thermally stable as characterized using Differential Scanning Calorimetry. The decomposition temperature is often greater than 350° C. Solutions of the small molecule semiconductors of Formula (I) are stable under ambient conditions and typical room lighting conditions for extended periods. For example, no color change was observed in solutions after several weeks of storage under ambient conditions and typical room lighting conditions. The good stability results from the anthracene structure. Anthracene derivatives often show better stability than pentacene or pentacene derivatives because of their shorter conjugation. The silylethynyl groups substituted at 9,10 positions prevent these molecules from undergoing the Diels-Alder addition reaction with singlet oxygen or with themselves (dimerization reaction).

In a second aspect, a composition such as a coating composition is provided that includes (a) a small molecule semiconductor of Formula (I) and (b) an organic solvent. The composition contains at least 0.1 weight percent dissolved small molecule semiconductor of Formula (I) based on the total weight of the composition. Any organic solvent that can provide this minimum solubility can be used. The organic solvent is often selected based on the R¹ and R² groups present on the small molecule semiconductor of Formula (I). In some applications, the organic solvent is also selected to have a relatively high boiling point and relatively low toxicity. For example, for some but not all applications, it is desirable to use an organic solvent having a boiling point greater than 80° C., greater than 90° C., or greater than 100° C. The composition can be, for example, used to form a semiconductor layer in a semiconductor device.

A first suitable type of organic solvent has a single aromatic ring that can be optionally substituted with one or more alkyl groups. That is, the first suitable type of organic solvent can be a benzene that is unsubstituted or substituted with at least one alkyl group. Examples of this first type of organic solvent include, but are not limited to, benzene, toluene, xylene, o-xylene, m-xylene, p-xylene, ethylbenzene, n-propylbenzene, n-butylbenzene, n-pentylbenzene, and n-hexylbenzene. A second suitable type of organic solvent is an alkane that is substituted with one or more halo groups. Examples of this second type of organic solvent include, but are not limited to, chloroform, 1,2-dichloroethane, 1,1,2,2-tetrachloroethane, and trichloroethane. A third suitable type of organic solvent has a single aromatic ring that is substituted with one or more halo groups. That is, the third suitable type of organic solvent can be benzene substituted with at least one halo group. Examples of this third type of organic solvent include, but are not limited to, chlorobenzene and dichlorobenzene. A fourth suitable type of organic solvent is a ketone that is cyclic, linear, branched, or a combination thereof. Examples of this fourth type of organic solvent include, but are not limited to, acetone, methylethylketone, methylisobutylketone, isophorone, 2,4-pentanedione, cyclopentanone, cyclohexanone, 2-methylcyclopentone, 3-methylcyclopentanone, 2,4-dimethylcyclopentanone, and 1,3-cyclohexanone. A fifth suitable type of organic solvent is an ether such as a cyclic ether or aromatic ether. Examples of this fifth type of organic solvent include, but are not limited to, 1,4-dioxane, tetrahydrofuran (THF), and anisole. A sixth suitable type of organic solvent is an amide. Examples of this sixth type of organic solvent include, but are not limited to, N,N-dimethylformamide (DMF) and N,N-dimethylacetamide (DMAc). A seventh suitable type of organic solvent is an alkane such as those have at least 6 carbon atoms. Examples of this seventh type of organic solvent include, but are not limited to, octane, nonane, decane, and dodecane. In some embodiments, the solvent is a mixture of various organic solvents of the same type or a mixture of various organic solvents of different types.

The concentration of small molecule semiconductor in the composition is often at least 0.1 weight percent, at least 0.2 weight percent, at least 0.3 weight percent, at least 0.5 weight percent, at least 1.0 weight percent, at least 1.5 weight percent, or at least 2.0 weight percent based on the total weight of the composition. The concentration of the small molecule semiconductor is often up to 10 weight percent, up to 5 weight percent, up to 4 weight percent, up to 3 weight percent, or up to 2 weight percent based on the total weight of the composition. In many embodiments, at least 50 weight percent, at least 60 weight percent, at least 70 weight percent, at least 80 weight percent, at least 90 weight percent, at least 95 weight percent, at least 98 weight percent, or at least 99 weight percent of the small molecule semiconductor is dissolved in the composition. In these embodiments, the composition can include both dissolved and dispersed or suspended small molecule semiconductor of Formula (I). In some embodiments, the entire amount of the small molecule semiconductor present in the composition is dissolved. That is, in these embodiments, the small molecule semiconductor can be entirely dissolved in the composition.

In some embodiments, the compositions can further include an insulating polymer. Any insulating polymer that dissolves in an organic solvent suitable for the small molecule semiconductor can be used in the composition. Suitable insulating polymers typically do not have conjugated carbon-carbon double bonds along the backbone of the polymer. That is, the insulating polymers are non-conductive over the length of the polymeric chain. The insulating polymer, however, can have regions with conjugated carbon-carbon double bonds. For example, the insulating polymer can have pendant conjugated aromatic groups. In some embodiments, the insulating polymer is aliphatic and has few, if any, carbon-carbon double bonds.

The insulating polymer is often an amorphous material. Exemplary insulating polymers include, but are not limited to, polystyrene (PS), poly(α-methylstyrene) (PαMS), poly(methyl methacrylate) (PMMA), polyvinylphenol (PVP), poly(vinyl alcohol) (PVA), poly(vinyl acetate) (PVAc), polyvinylchloride (PVC), polyvinyldenfluoride (PVDF), cyanoethylpullulan (CYPEL), poly(divinyltetramethyldisiloxane-bis(benzocyclobutene)) (BCB), and the like.

The insulating polymer can have any suitable molecular weight that can be dissolved in the organic solvent. The molecular weight of the insulating polymer can influence the viscosity of the composition. Insulating polymers with a higher molecular weight tend to result in compositions with higher viscosity. If the composition is used to prepare a coating layer, the desired viscosity may depend, at least in part, on the method used to prepare a coating layer. For example, lower viscosity compositions can be used with inkjet methods compared to knife coating methods.

In many embodiments, however, the molecular weight of the insulating polymer is at least 1000 g/mole, at least 2000 g/mole, at least 5000 g/mole, at least 10,000 g/mole, at least 20,000 g/mole, at least 50,000 g/mole, or at least 100,000 g/mole. The molecular weight is often no greater than 1,000,000 g/mole, no greater than 500,000 g/mole, no greater than 200,000 g/mole, or no greater than 100,000 g/mole. The molecular weight is often in the range of 1000 to 1,000,000 g/mole, in the range of 2000 to 500,000 g/mole, or in the range of 2000 to 200,000 g/mole.

The concentration of the insulating polymer in the composition is often at least 0.1 weight percent, at least 0.2 weight percent, at least 0.5 weight percent, at least 1.0 weight percent, at least 1.5 weight percent, at least 2.0 weight percent, at least 2.5 weight percent, at least 3 weight percent, at least 5 weight percent, or at least 10 weight percent based on the total weight of the composition. The lower concentration limit can depend on the use of the composition. If the composition is applied to a surface using an inkjet method to form a coating layer, the concentration of the insulating polymer is often at least 0.5 weight percent based on the total weight of the composition. Lower concentrations may have an undesirably low viscosity. If the composition is applied to a surface using a different technique such as knife coating to form a coating layer, however, the viscosity of the composition can be lower (i.e., the concentration of the insulating polymer can be less than 0.5 weight percent based on the total weight of the composition).

The concentration of the insulating polymer in the composition is often up to 20 weight percent, up to 10 weight percent, up to 5 weight percent, up to 4 weight percent, or up to 3 weight percent based on the total weight of the composition. If the concentration is too high, the viscosity of the composition may be unacceptably high for many applications. Typically, the upper limit is determined by the solubility of the insulating polymer in the composition. The insulating polymer is typically dissolved or substantially dissolved rather than dispersed or suspended in the composition. As used herein, the term “substantially dissolved” means that the insulating polymer is dissolved but may contain an impurity that is not dissolved in the composition. At least 98 weight percent, at least 99 weight percent, at least 99.5 weight percent, at least 99.8 weight percent, or at least 99.9 weight percent of the insulating polymer is dissolved in the composition.

Any ratio of the small molecule semiconductor to the insulting polymer can be used in the composition. In some applications, the weight ratio of the small molecule to the insulating polymer is in the range of 1:10 to 20:1, in the range of 1:10 to 10:1, in the range of 1:8 to 8:1, in the range of 1:5 to 5:1, in the range of 1:4 to 4:1, in the range of 1:3 to 3:1, or in the range of 1:2 to 2:1.

The percent solids of the composition can be any desired amount but is typically in the range of 0.2 to 30 weight percent based on the total weight of the composition. The percent solids is often in the range of 0.5 to 20 weight percent, in the range of 0.5 to 10 weight percent, in the range of 0.5 to 5 weight percent, or in the range of 1 to 5 weight percent. In many embodiments, the percent solids is limited by the solubility of the small molecule semiconductor of Formula (I) plus the solubility of the insulating polymer in the organic solvent.

The compositions are often used to prepare a semiconductor layer in a semiconductor device. Thus, in another aspect, a semiconductor device is provided that contains a semiconductor layer. The semiconductor layer includes (a) a small molecule semiconductor of Formula (I). In some embodiments, the semiconductor layer further includes an insulating polymer.

Semiconductor devices have been described, for example, by S. M. Sze in Physics of Semiconductor Devices, 2^{nd} edition, John Wiley and Sons, New York (1981). These semiconductor devices include rectifiers, transistors (of which there are many types, including p-n-p, n-p-n, and thin-film transistors), photoconductors, current limiters, thermistors, p-n junctions, field-effect diodes, Schottky diodes, and the like. Semiconductor devices can include components such as transistors, arrays of transistors, diodes, capacitors, embedded capacitors, and resistors that are used to form circuits. Semiconductor devices also can include arrays of circuits that perform an electronic function. Examples of these arrays or integrated circuits include inverters, oscillators, shift registers, and logic circuits. Applications of these semiconductor devices and arrays include radio frequency identification devices (RFIDs), smart cards, display backplanes, sensors, memory devices, and the like.

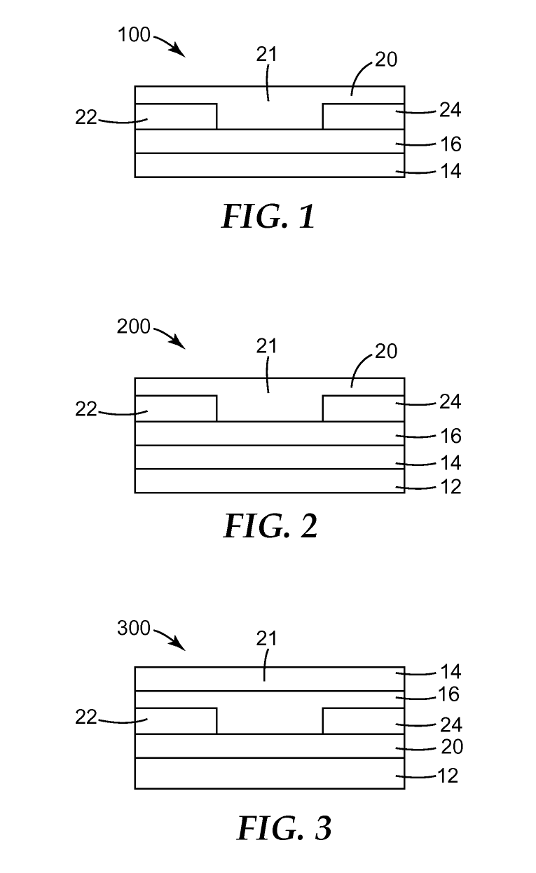

Some of the semiconductor devices are organic thin-film transistors as shown schematically in FIGS. 1 to 6. Any given layer in the various thin film transistors shown in FIGS. 1 to 6 can include multiple layers of materials. Further, any layer can include a single material or multiple materials. Further, as used herein, the terms “disposed”, “disposing”, “deposited”, “depositing”, and “adjacent” do not preclude another layer between the mentioned layers. As used herein, these terms mean that a first layer is positioned near a second layer. The first layer often contacts the second layer but another layer could be positioned between the first layer and the second layer.

One embodiment of an organic thin-film transistor 100 is shown schematically in FIG. 1. The organic thin-film transistor (OTFT) 100 includes a gate electrode 14, a gate dielectric layer 16 disposed on the gate electrode 14, a source electrode 22, a drain electrode 24, and a semiconductor layer 20 that is in contact with both the source electrode 22 and the drain electrode 24. The source electrode 22 and the drain electrode 24 are separated from each other (i.e., the source electrode 22 does not contact the drain electrode 24) and are positioned adjacent to the dielectric layer 16. Both the source electrode 22 and the drain electrode 24 are in contact with the semiconductor layer 20 such that a portion of the semiconductor layer is positioned between the source electrode and the drain electrode. The portion of the semiconductor layer that is positioned between the source electrode and the drain electrode is referred to as the channel 21. The channel is adjacent to the gate dielectric layer 16. Some semiconductor devices have an optional surface treatment layer between the gate dielectric layer 16 and the semiconductor layer 20.

An optional substrate can be included in the organic thin-film transistors. For example, the optional substrate 12 can be adjacent to the gate electrode 14 as shown schematically in FIG. 2 for the OTFT 200 or adjacent to the semiconductor layer 20 as shown schematically in FIG. 3 for the OTFT 300. The OTFT 300 can include an optional surface treatment layer between the substrate 12 and the semiconductor layer 20.

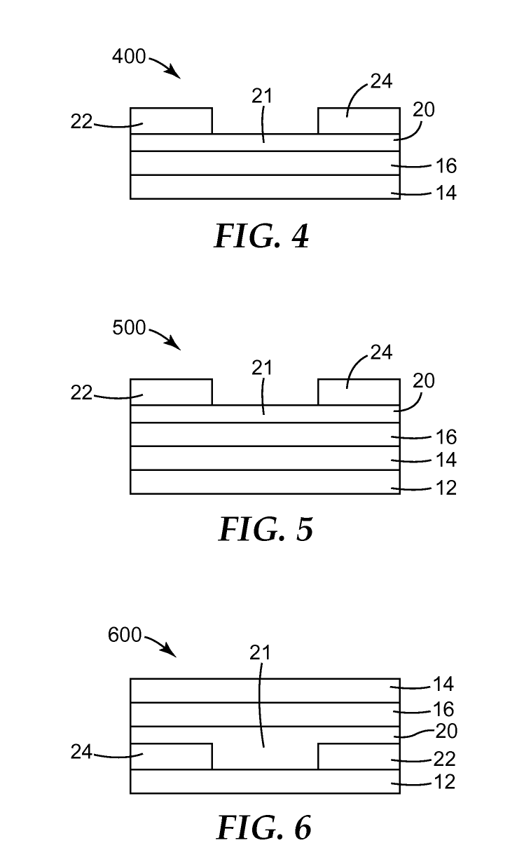

Another embodiment of an organic thin-film transistor is shown schematically in FIG. 4. This organic thin-film transistor 400 includes a gate electrode 14, a gate dielectric layer 16 disposed on the gate electrode 14, a semiconductor layer 20, and a source electrode 22 and a drain electrode 24 disposed on the semiconductor layer 20. In this embodiment, the semiconductor layer 20 is between the gate dielectric layer 16 and both the source electrode 22 and the drain electrode 24. The source electrode 22 and the drain electrode 24 are separated from each other (i.e., the source electrode 22 does not contact the drain electrode 24). Both the source electrode 22 and the drain electrode 24 are in contact with the semiconductor layer such that a portion of the semiconductor layer is positioned between the source electrode and the drain electrode. The channel 21 is the portion of the semiconductor layer that is positioned between the source electrode 22 and the drain electrode 24. One or more optional surface treatment layers can be included in the semiconductor device. For example, an optional surface treatment layer can be included between the gate dielectric layer 16 and the semiconductor layer 20.

An optional substrate can be included in the organic thin-film transistors. For example, the optional substrate 12 can be in contact with the gate electrode 14 as shown schematically in FIG. 5 for the OTFT 500 or in contact with the semiconductor layer 20 as shown schematically in FIG. 6 for the OTFT 600. OTFT 600 can include an optional surface treatment layer between the substrate 12 and the semiconductor layer 20.

In operation of the semiconductor device configurations shown in FIGS. 1 to 6, voltage can be applied to the drain electrode 24. However, at least ideally, no charge (i.e., current) is passed to the source electrode 22 unless voltage is also applied to the gate electrode 14. That is, unless voltage is applied to the gate electrode 14, the channel 21 in the semiconductor layer 20 remains in a non-conductive state. Upon application of voltage to the gate electrode 14, the channel 21 becomes conductive and charge flows through the channel 21 from the source electrode 22 to the drain electrode 24.

A substrate 12 often supports the OTFT during manufacturing, testing, and/or use. Optionally, the substrate can provide an electrical function for the OTFT. For example, the backside of the substrate can provide electrical contact. Useful substrate materials include, but are not limited to, inorganic glasses, ceramic materials, polymeric materials, filled polymeric materials (e.g., fiber-reinforced polymeric materials), metals, paper, woven or non-woven cloth, coated or uncoated metallic foils, or a combination thereof.

The gate electrode 14 can include one or more layers of a conductive material. For example, the gate electrode can include a doped silicon material, a metal, an alloy, a conductive polymer, or a combination thereof. Suitable metals and alloys include, but are not limited to, aluminum, chromium, gold, silver, nickel, palladium, platinum, tantalum, titanium, indium tin oxide (ITO), fluorine tin oxide (FTO), antimony doped tin oxide (ATO), or a combination thereof. Exemplary conductive polymers include, but are not limited to, polyaniline, poly(3,4-ethylenedioxythiophene)/poly(styrene sulfonate), or polypyrrole. In some organic thin film transistors, the same material can provide both the gate electrode function and the support function of the substrate. For example, doped silicon can function as both the gate electrode and as the substrate.

The gate electrode in some embodiments is formed by coating a substrate surface with a dispersion that contains conductive materials such as nanoparticles that are conductive or polymeric materials that are conductive. Conductive nanoparticles include, but are not limited to, ITO nanoparticles, ATO nanoparticles, silver nanoparticles, gold nanoparticles, or carbon nanotubes.

The gate dielectric layer 16 is disposed on the gate electrode 14. This gate dielectric layer 16 electrically insulates the gate electrode 14 from the balance of the OTFT device. Useful materials for the gate dielectric include, for example, an inorganic dielectric material, a polymeric dielectric material, or a combination thereof. The gate dielectric can be a single layer or multiple layers of suitable dielectric materials. Each layer in a single or multilayer dielectric can include one or more dielectric materials.

The organic thin film transistors can include an optional surface treatment layer disposed between the gate dielectric layer 16 and at least a portion of the organic semiconductor layer 20 or disposed between the substrate 12 and at least a portion of the organic semiconductor layer 20. In some embodiments, the optional surface treatment layer serves as an interface between the gate dielectric layer and the semiconductor layer or between the substrate and the semiconductor layer. The surface treatment layer can be a self-assembled monolayer as described in U.S. Pat. No. 6,433,359 B1 (Kelley et al.) or a polymeric material as described in U.S. Pat. No. 6,946,676 (Kelley et al.), and U.S. Pat. No. 6,617,609 (Kelley et al.).

The source electrode 22 and drain electrode 24 can be metals, alloys, metallic compounds, conductive metal oxides, conductive ceramics, conductive dispersions, and conductive polymers, including, for example, gold, silver, nickel, chromium, barium, platinum, palladium, aluminum, calcium, titanium, indium tin oxide (ITO), fluorine tin oxide (FTO), antimony tin oxide (ATO), indium zinc oxide (IZO), poly(3,4-ethylenedioxythiophene)/poly(styrene sulfonate), polyaniline, other conducting polymers, alloys thereof, combinations thereof, and multiple layers thereof. Some of these materials are appropriate for use with n-type semiconductor materials and others are appropriate for use with p-type semiconductor materials, as is known in the art.

The thin film electrodes (e.g., the gate electrode, the source electrode, and the drain electrode) can be provided by any means known in the art such as physical vapor deposition (for example, thermal evaporation or sputtering), ink jet printing, or the like. The patterning of these electrodes can be accomplished by known methods such as shadow masking, additive photolithography, subtractive photolithography, printing, microcontact printing, and pattern coating.

In yet another aspect, a method of making a semiconductor device is provided. The method includes providing a semiconductor layer that contains a small molecule semiconductor of Formula (I). Although any suitable method can be used to provide the semiconductor layer, this layer is often provided using a composition. The composition can be the same as described above. In some embodiments, both the composition and the resulting semiconductor layer include an insulating polymer in addition to the small molecule semiconductor of Formula (I).

In some exemplary methods of preparing a semiconductor device, the method involves providing a first layer selected from a dielectric layer or a conductive layer and disposing a semiconductor layer adjacent to the first layer. No specific order of preparing or providing is necessary; however, the semiconductor layer is often prepared on the surface of another layer such as the dielectric layer, the conductive layer, or a substrate. The conductive layer can include, for example, one or more electrodes such as a gate electrode or a layer that includes both the source electrode and the drain electrode. The step of disposing a semiconductor layer adjacent to the first layer includes often includes (1) preparing a composition that includes the small molecule semiconductor of Formula (I) and an organic solvent that dissolves at least a portion of the small molecule semiconductor, (2) applying the composition to the first layer to form a coating layer, and (3) removing at least a portion of the organic solvent from the coating layer. The composition contains at least 0.1 weight percent dissolved small molecule semiconductor based on the total weight of the composition. Often, the composition also contains at least 0.1 weight percent dissolved insulating polymer.

Some of the methods of preparing semiconductor devices are methods of preparing organic thin film transistors. One method of preparing an organic thin film transistor involves arranging multiple layers in the following order: a gate electrode; a gate dielectric layer; a layer having a source electrode and a drain electrode that are separated from each other; and a semiconductor layer in contact with both the source electrode and the drain electrode. The semiconductor layer includes a small molecule semiconductor of Formula (I) and an optional insulating polymer. Exemplary organic thin film transistors according to this method are shown schematically in FIGS. 1 to 6.

For example, the organic thin film transistor shown schematically in FIG. 1 can be prepared by providing a gate electrode 14; depositing a gate dielectric layer 16 adjacent to the gate electrode 14; positioning a source electrode 22 and a drain electrode 24 adjacent to the gate dielectric layer 16 such that the source electrode 22 and the drain electrode 24 are separated from each other; and forming a semiconductor layer 20 that is deposited on the source electrode 22, on the drain electrode 24, and in the area 21 between the source electrode 22 and the drain electrode 24. The semiconductor layer 20 contacts both the source electrode 22 and the drain electrode 24. The portion of the semiconductor layer that is positioned in the area between the source electrode and the drain electrode defines a channel.

The organic thin film transistor shown schematically in FIG. 2 can be prepared by providing a substrate 12; depositing a gate electrode 14 on the substrate 12; depositing a gate dielectric layer 16 adjacent to the gate electrode 14 such that the gate electrode 14 is positioned between the substrate 12 and the gate dielectric layer 16; positioning a source electrode 22 and a drain electrode 24 adjacent to the gate dielectric layer 16 such that the two electrodes are separated from each other; and forming a semiconductor layer 20 adjacent to the source electrode 22, the drain electrode 24, and in the area 21 between the source electrode 22 and the drain electrode 24. The semiconductor layer 20 contacts both the source electrode 22 and the drain electrode 24. The portion of the semiconductor layer that is positioned in the area between the source electrode and the drain electrode defines a channel.

The organic thin film transistor shown schematically in FIG. 3 can be prepared by providing a substrate 12; forming a semiconductor layer 20 adjacent to the substrate 12; positioning a source electrode 22 and a drain electrode 24 adjacent to the semiconductor layer 20 opposite the substrate 12 such that the source electrode 22 and drain electrodes 24 are separated from each other; depositing a gate dielectric layer 16 adjacent to the source electrode 22, the drain electrode 24, and a portion of the semiconductor layer 20 between the source electrode 22 and the drain electrode 24; and depositing a gate electrode 14 adjacent to the gate dielectric layer 16. Both the source electrode 22 and the drain electrode 24 contact the semiconductor layer 20. A portion of the semiconductor layer is positioned between the source electrode 22 and the drain electrode 24. This portion of the semiconductor layer defines a channel.

The organic thin film transistors shown schematically in FIGS. 4 to 6 can be prepared by a method that involves arranging multiple layers in the following order: a gate electrode; a gate dielectric layer; a semiconductor layer containing semiconductor of Formula (I) and an optional insulating polymer; and a layer having a source electrode and a drain electrode that are separated from each other, wherein the semiconductor layer contacts both the drain electrode and the source electrode. In some embodiments, a surface treatment layer can be positioned between the gate dielectric layer and the semiconductor layer. A substrate can be positioned adjacent to the gate electrode or adjacent to the layer containing the source electrode and the drain electrode.

For example, the organic thin film transistor shown schematically in FIG. 4 can be prepared by providing a gate electrode 14; depositing a gate dielectric layer 16 adjacent to the gate electrode 14; forming a semiconductor layer 20 adjacent to the gate dielectric layer 16 (i.e., the gate dielectric layer 16 is positioned between the gate electrode 14 and the semiconductor layer 20); and positioning a source electrode 22 and a drain electrode 24 adjacent to the semiconductor layer 20. The source electrode 22 and the drain electrode 24 are separated from each other and both electrodes are in contact with the semiconductor layer 20. A portion of the semiconductor layer is positioned between the source and drain electrodes.

The organic thin film transistor shown schematically in FIG. 5 can be prepared by providing a substrate 12, depositing a gate electrode 14 adjacent to the substrate 12, depositing a gate dielectric layer 16 adjacent to the gate electrode 14 such that the gate electrode 14 is positioned between the substrate 12 and the gate dielectric layer 16; forming a semiconductor layer 20 adjacent to the gate dielectric layer 16; and positioning a source electrode 22 and a drain electrode 24 adjacent to the semiconductor layer 20. The source electrode 22 and the drain electrode 24 are separated from each other and both electrodes are in contact with the semiconductor layer 20. A portion of the semiconductor layer 20 is positioned between the source electrode 22 and the drain electrode 24.

The organic thin film transistor shown schematically in FIG. 6 can be prepared by providing a substrate 12; positioning a source electrode 22 and a drain electrode 24 adjacent to the substrate such that the source electrode 22 and the drain electrode 24 are separated from each other; forming a semiconductor layer 20 that contacts the source electrode 22 and the drain electrode 24; and depositing a gate dielectric layer 16 adjacent to the semiconductor layer opposite the source electrode 22 and the drain electrode 24; and depositing a gate electrode 14 adjacent to the gate dielectric layer 16. A portion of the semiconductor layer 20 is positioned between the source electrode 22 and the drain electrode 24.

In any of the organic thin film transistors shown schematically in FIGS. 1 to 6, the semiconductor layer can be formed by (1) preparing a composition that contains the small molecule semiconductor of Formula (I), an optional insulating polymer, and an organic solvent that dissolves at least a portion of both the small molecule semiconductor and the optional insulating polymer, (2) applying the composition to another layer of the organic thin film transistor, and (3) removing at least a portion of the organic solvent. The composition contains at least 0.1 weight percent dissolved small molecule semiconductor based on the total weight of the composition and can optionally further contain at least 0.1 weight percent dissolved insulating polymer.

### EXAMPLES

All reagents were purchased from commercial sources and used without further purification unless otherwise noted.

Sodium carbonate, tin (II) chloride, bis(pinacollato)diboron, tetrakis(triphenylphosphine)palladium(0), 4-bromoanisole, and 2-bromo-6-methoxynaphthalene were purchased from SigmaAldrich (Milwaukee, Wis.).

ALIQUAT 336 (a phase transfer catalyst), n-butyl lithium, and [1,1′-bis(diphenylphosphino)ferrocene]dichloropalladium complex with dichloromethane were obtained from Alfa Aesar (Ward Hill, Mass.).

Triisopropylsilylacetylene and was purchased from GFS Chemicals (Columbus, Ohio).

Hexane and tetrahydrofuran (THF) were distilled over sodium.

The molecular structures of all products and intermediates were confirmed by ¹H-NMR (400 MHz). The following starting materials were prepared using published procedures as follows:

2,6-dibromoanthraquinone was prepared from commercially available 2,6-diaminoanthraquinone (Sigma Aldrich) as described by Ito et al., Angew. Chem. Int. Ed., 42, 1159-1162 (2003). After sublimation, it was further purified by recrystallization from DMF.

The precursor 2,6-bis-(4,4,5,5-tetramethyl-1,3,2-dioxaborolan-2-yl)-9,10-bis-[(triisopropylsilyl)ethynyl]anthracene was synthesized according to Reaction Scheme 1, as described in Preparatory Examples 1 and 2.

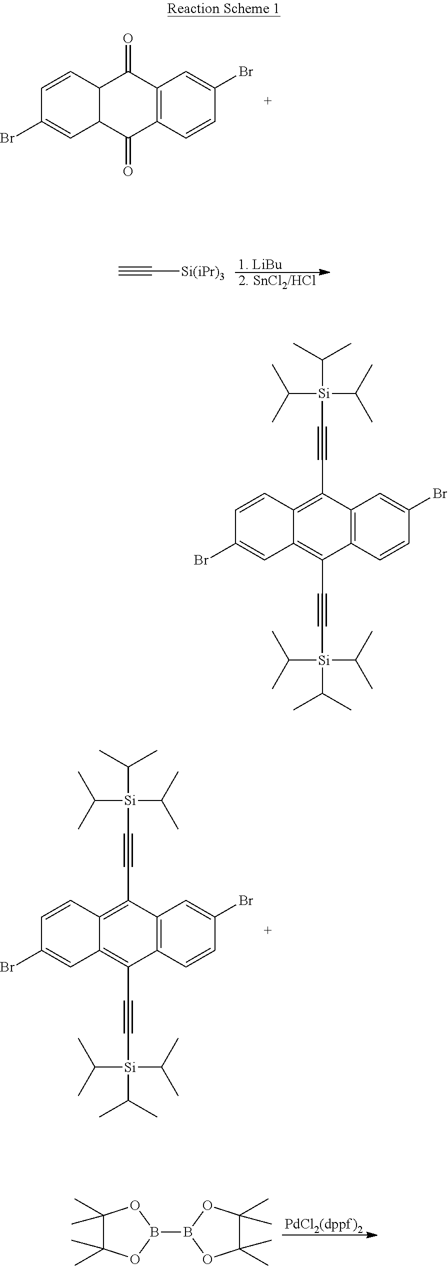

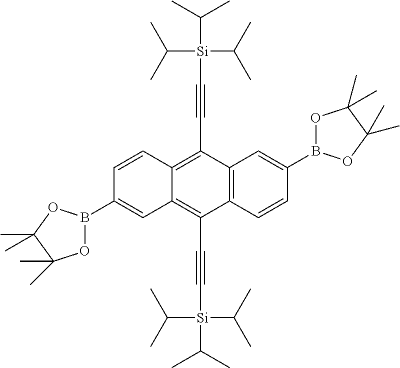

A Suzuki coupling reaction was used to synthesize various compounds of Formula (I) as shown in Reaction Scheme 2. In Example 1, the precursor 2,6-bis-(4,4,5,5-tetramethyl-1,3,2-dioxaborolan-2-yl)-9,10-bis-[(triisopropylsilyl)ethynyl]anthracene was reacted with 4-bromoanisol (R¹—Br in Reaction Scheme 2). In Example 2, the same precursor was reacted with 2-bromo-6-methoxynaphthalene (R¹—Br in Reaction Scheme 2).

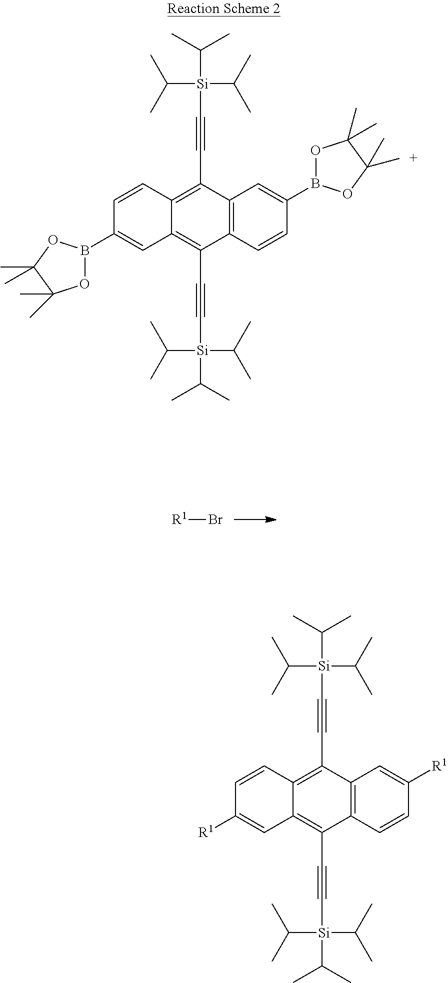

### Preparatory Example 1

### Synthesis of 2,6-dibromo-9,10-bis[(triisopropylsilyl)-ethynyl]anthracene

Triisopropylsilylacetylene (12.32 g, 67.5 mmol) and dry hexane (140 mL) were added under a dry nitrogen blanket to an oven-dried round bottom flask (1 L). Butyl lithium (2.7 M in hexane, 14.5 mL, 39.2 mmol) was added dropwise under dry nitrogen through a syringe to the mixture. The mixture was stirred at room temperature for 2 hours. To this colorless solution, dry THF (300 mL) and 2,6-dibromoanthraquinone (5.49 g, 15.0 mmol) were added under dry nitrogen. The solution turned red immediately and the 2,6-dibromoanthraquininone dissolved in minutes. The mixture was stirred at room temperature overnight and the solution became dark red. Deionized (DI) water (6.0 mL) was added, the color changed to light red, and a white precipitate appeared. Tin (II) chloride (8.088 g, 42.6 mmol) in HCl (18 mL, 10%) aqueous solution was then added. The mixture was heated to 60° C. for 2 hours and then cooled to room temperature. The solvent was removed by rotary evaporation. DI water (100 mL) was added to the mixture which was then extracted with hexane (100 mL×3). The hexane solution was washed with DI water until neutral. It was concentrated and purified through a column chromatography (silica gel/hexane). A bright yellow solid (8.55 g, yield: 82%) was obtained as the product.

### Preparatory Example 2

### Synthesis of 2,6-bis-(4,4,5,5-tetramethyl-1,3,2-dioxaborolan-2-yl)-9,10-bis[(triisopropylsilyl)ethynyl]anthracene

2,6-dibromo-9,10-bis-[(triisopropylsilyl)ethynyl]anthracene (5.225 g, 7.5 mmol) from Preparatory Example 1, bis(pinacollato)diboron (4.763 g, 18.8 mmol), KOAc (2.940 g, 30.0 mmol), and CHCl₃ (100 mL) were charged to a 250 ml flask under dry nitrogen. A yellow solution with suspended KOAc was obtained. The suspension was degassed to remove traces of oxygen. [1,1′-bis(diphenylphosphino)ferrocene]dichloropalladium (0.205 g) was then added under dry nitrogen. The solution turned orange. The mixture was stirred at 70° C. for 3 days and then cooled to room temperature. It was washed with DI water (100 mL×3) and dried over MgSO₄. The solvent was removed by rotary evaporation. The solid residue was purified by column chromatography (silica gel, CHCl₃) and recrystallized from ethyl acetate. Orange needle crystals were obtained (3.20 g, yield 55%) as the product.

### Example 1

### Synthesis of 2,6-Bis(4-methoxy-phenyl)-9,10-bis-[(triisopropylsilyl)ethynyl]anthracene (B4MP-TIPS-An)

A 250 mL Schlenk flask was charged with 2,6-bis-(4,4,5,5-tetramethyl-1,3,2-dioxaborolan-2-yl)-9,10-bis-[(triisopropylsilyl)ethynyl]anthracene (1.266 g, 1.60 mmol), 4-bromoanisol (0.748 g, 4.00 mmol), sodium carbonate (0.848 g, 8.00 mmol), ALIQUAT 336 (0.072 g, a mixture of [CH₃(CH₂)₉]₃NCH₃⁺Cl⁻ and [CH₃(CH₂)₇]₃NCH₃⁺Cl⁻, used as a phase transfer catalyst), distilled water (25 mL), and toluene (100 mL). The mixture was degassed under nitrogen using a Schlenk line to remove oxygen. Tetrakis(triphenylphosphine)palladium(0) (0.024 g, 0.02 mmol) was then added under nitrogen flow. After degassing one more time, the mixture was stirred under nitrogen at 90° C. The upper organic layer turned to greenish orange, and the lower aqueous layer was colorless. After being stirred at 90° C. for 20 hours, the mixture was cooled to room temperature. A little insoluble black solid was filtered out. Dark green toluene solution was concentrated to ˜15 mL by rotary evaporation then quenched in MeOH (100 mL). Orange solid (1.13 g) was collected by filtration. It was purified by zone sublimation. The vacuum was 1.1×10⁻⁶ Ton, source zone temperature was 260° C. and center zone temperature was 200° C. Nice red/orange crystal (1.0) was obtained as product.

### Example 2

### Synthesis of 2,6-Bis-(6-methoxy-naphthalen-2-yl)-9,10-bis-[(triisopropylsilanyl)-ethynyl]-anthracene (BMN-TIPS-An)

A 250 mL Schlenk flask was charged with 2,6-bis-(4,4,5,5-tetramethyl-1,3,2-dioxaborolan-2-yl)-9,10-bis-[(triisopropylsilyl)ethynyl]anthracene (1.266 g, 1.60 mmol), 2-bromo-6-methoxynaphthalene (0.949 g, 4.00 mmol), sodium carbonate (0.848 g, 8.00 mmol), ALIQUAT 336 (0.072 g, a mixture of [CH₃(CH₂)₉]₃NCH₃⁺Cl⁻ and [CH₃(CH₂)₇]₃NCH₃⁺Cl⁻, used as a phase transfer catalyst), distilled water (25 mL), and toluene (100 mL). The mixture was degassed three times under nitrogen using a Schlenk line to remove oxygen. Tetrakis(triphenylphosphine)palladium(0) (0.024 g, 0.02 mmol) was then added under nitrogen flow. After degassing one more time, the mixture was stirred under nitrogen at 90° C. The red upper organic layer turned to dark green in ˜1 hour and the lower aqueous layer was colorless. After being stirred at 90° C. for 20 hours, the mixture was cooled to room temperature. A little insoluble black solid was filtered out. Dark green toluene solution was concentrated to ˜15 mL by rotary evaporation then quenched in MeOH (100 mL). Orange solid (1.15 g) was collected by filtration. It was further purified by zone sublimation. The vacuum was 3˜5×10⁻⁶ Torr, source zone temperature was 300° C. and center zone temperature was 220° C. Orange solid (0.4 g) was collected in the central zone.

### Example 3

### Solubility Measurement

The solubility of B4MP-TIPS-An, which was synthesized in Example 1, was measured in various solvents at room temperature. This small molecule semiconductor had moderate solubility in n-butylbenzene (about 1.0 weight percent) and good solubility in dichlorobenzene (greater than 6.0 weight percent) and xylene (about 3.5 weight percent). The weight percent is based on the total solution weight.

### Example 4

### Thin Film Transistor (TFT) Device Preparation and Characterization

Heavily doped Si wafers (Si 100, Silicon Valley Microelectronics, Inc., Santa Clara, Calif.) was pretreated with 1,1,1,3,3,3-hexamethyldisilazane (HMDS) by spin coating at 1000 rpm for 30 seconds. B4MP-TIPS-An and polystyrene (Mw=97400, Sigma Aldrich) were dissolved in xylene at RT so their concentrations were 3.0 weight percent and 1.0 weight percent respectively based on the total weight of the composition. The solution was then knife coated on a piece of HMDS-treated substrate. After air-drying, the samples were annealed at 120° C. for 30 minutes in air. Gold source/drain electrodes (60 nm thick) were patterned through a polymer shadow mask using thermal evaporation method under a vacuum of 2×10⁻⁶ Torr. Thin film transistors were characterized under ambient conditions using a Hewlett Packard Semiconductor Parameter Analyzer (Model 4145A, available from Hewlett Packard Corporation, Palo Alto, Calif.) by sweeping the gate voltage (V_{g}) from +10 V to −40 V, while keeping the drain voltage (V_{ds}) at −40 V. A linear fit to the I_{d}^{1/2}−V_{g} trace permitted the extraction of the saturation mobility and the threshold voltage (Vₜ). A linear fit to the I_{d}−V_{g} trace allowed the current on/off ratio to be calculated. The hole mobility μ was calculated to be 0.21 cm²/Vs; the threshold voltage was −8V; and the On/Off ratio was 6×10⁴.

### Example 5

### Stability Test of Thin Film Transistor (TFT) Devices

B4MP-TIPS-An TFT devices were fabricated according to the procedure described in Example 4. The composition of the semiconductor solution used in this experiment was 3.0 wt % of B4MP-TIPS-An, 2.0 wt % of polystyrene, and 95.0 wt % of xylene based on total solution weight. Sixteen TFT devices were randomly selected and tested for TFT properties right after the sample was prepared. The sample was put in an air oven setting at 120° C. TFT properties of these sixteen devices were re-measured after being aged for 3 days and 7 days. All sixteen tested devices functioned very well after these aging periods. As can be seen in Table 1, the mobility of the devices slightly decreased to about 75 percent of their original values after being aged for 3 days and retained about 50 percent after being aged 7 days at 120° C. in air. Surprisingly, the On/Off ratio and the subthreshold slope showed great improvement after aging. On average, the mobility decreased from 0.079 cm²/Vs to 0.059 cm²/Vs (3 days) and 0.039 cm²/Vs (7 days); the On/Off ratio increased from 1.0×10⁴ to 1.7×10⁴ (3 days) and 8.7×10⁴ (7 days); and the subthreshold slope decreased from 3.2 V/decade to 1.4 V/decade (3 days) and 1.5 V/decade (7 days), which indicates the devices turn on faster after being aged.

TABLE 1
Stability of B4MP-TIPS-An TFT devices at 120° C. in air.

| | Mobility (cm²/Vs) | | | On/Off (×10⁴) | | | Slope (V/decade) | | |
|---|---|---|---|---|---|---|---|---|---|
| Device | 0 day | 3 days | 7 days | 0 day | 3 days | 7 days | 0 day | 3 days | 7 days |
| 1 | 0.073 | 0.057 | 0.031 | 4.0 | 6.5 | 39.0 | 2.4 | 1.6 | 1.3 |
| 2 | 0.056 | 0.040 | 0.029 | 1.0 | 2.8 | 3.1 | 3.1 | 0.9 | 1.6 |
| 3 | 0.081 | 0.074 | 0.046 | 1.3 | 2.5 | 28.0 | 3.0 | 1.3 | 0.8 |
| 4 | 0.078 | 0.051 | 0.029 | 0.4 | 2.3 | 6.2 | 3.4 | 1.2 | 1.0 |
| 5 | 0.082 | 0.069 | 0.044 | 0.4 | 0.8 | 5.2 | 3.5 | 1.7 | 1.4 |
| 6 | 0.082 | 0.059 | 0.035 | 0.3 | 1.1 | 0.7 | 3.5 | 1.6 | 1.6 |
| 7 | 0.072 | 0.046 | 0.030 | 0.3 | 0.6 | 0.4 | 3.3 | 1.5 | 2.1 |
| 8 | 0.106 | 0.071 | 0.045 | 0.4 | 1.0 | 4.5 | 3.4 | 1.3 | 1.3 |
| 9 | 0.084 | 0.058 | 0.037 | 0.2 | 0.7 | 5.0 | 3.9 | 1.6 | 1.4 |
| 10 | 0.090 | 0.066 | 0.046 | 0.4 | 1.0 | 0.9 | 3.7 | 1.4 | 1.6 |
| 11 | 0.076 | 0.057 | 0.041 | 0.5 | 2.5 | 2.4 | 3.3 | 1.2 | 1.8 |
| 12 | 0.104 | 0.048 | 0.027 | 0.9 | 0.6 | 0.7 | 3.2 | 1.6 | 1.5 |
| 13 | 0.085 | 0.068 | 0.036 | 0.5 | 0.4 | 0.6 | 3.2 | 1.9 | 1.6 |
| 14 | 0.067 | 0.063 | 0.042 | 0.6 | 4.7 | 0.4 | 3.2 | 1.6 | 1.6 |
| 15 | 0.061 | 0.058 | 0.042 | 0.3 | 2.3 | 41.0 | 2.8 | 1.2 | 1.5 |
| 16 | 0.065 | 0.058 | 0.043 | 1.2 | 1.0 | 1.1 | 2.9 | 1.5 | 1.3 |
| Average | 0.079 | 0.059 | 0.038 | 1.0 | 1.7 | 8.7 | 3.2 | 1.4 | 1.5 |

1. A compound of Formula (I) 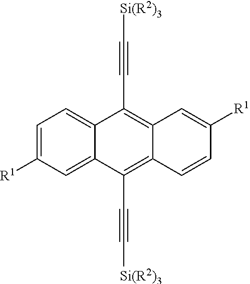
(I)
wherein
R¹ is a phenyl or naphthyl, wherein the phenyl or naphthyl is unsubstituted or substituted with one or more substituents selected from halogen, hydroxyl, amino, alkyl, alkenyl, alkoxy, acyloxy, heteroaryl, heteroalkyl, or heteroaralkyl; and
each R² is independently alkyl, alkenyl, alkoxy, aryl, heteroaryl, aralkyl, heteroalkyl, heteroaralkyl, or hydroxyalkyl.

2. The compound of claim 1, wherein R¹ is of Formula (II), (III), or (IV) 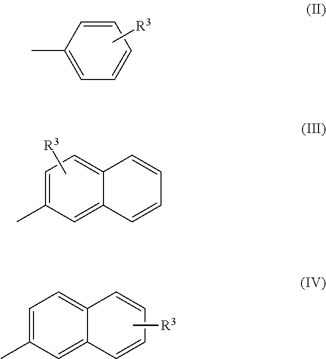
wherein
R³ is hydrogen, halogen, hydroxyl, amino, alkyl, alkenyl, alkoxy, acyloxy, heteroaryl, heteroalkyl, or heteroaralkyl.

3. The compound of claim 1, wherein R¹ is of Formula (V) or (VI) 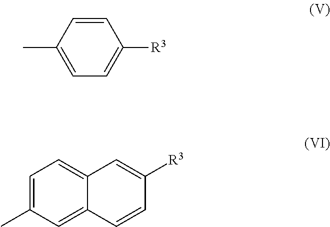
wherein
R³ is hydrogen, halogen, hydroxyl, amino, alkyl, alkenyl, alkoxy, acyloxy, heteroaryl, heteroalkyl, or heteroaralkyl.

4. The compound of claim 2, wherein R³ is alkoxy.

5. The compound of claim 1, wherein each R² is alkyl or alkenyl.

6. A composition comprising
(a) a small molecule semiconductor of Formula (I) 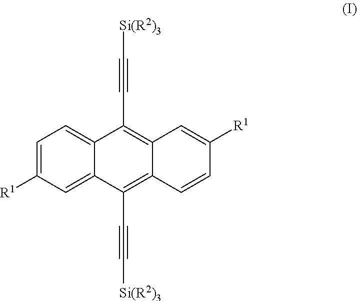
wherein
R¹ is a phenyl or naphthyl, wherein the phenyl or naphthyl is unsubstituted or substituted with one or more substituents selected from halogen, hydroxyl, amino, alkyl, alkenyl, alkoxy, acyloxy, heteroaryl, heteroalkyl, or heteroaralkyl; and
each R² is independently alkyl, alkenyl, alkoxy, aryl, heteroaryl, aralkyl, heteroalkyl, heteroaralkyl, or hydroxyalkyl; and
(b) an organic solvent.

7. The composition of claim 6, wherein the composition comprises at least 0.1 weight percent dissolved small molecule semiconductor of Formula (I) based on a total weight of the composition.

8. The composition of claim 6, wherein R¹ is of Formula (II), (III), or (IV) 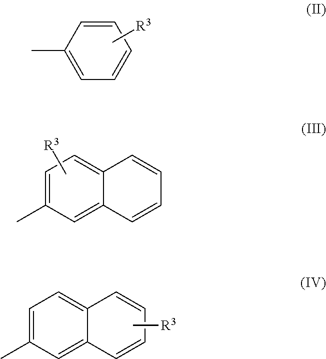
wherein
R³ is hydrogen, halogen, hydroxyl, amino, alkyl, alkenyl, alkoxy, acyloxy, heteroaryl, heteroalkyl, or heteroaralkyl.

9. The composition of claim 6, further comprising an insulating polymer.

10. The composition of claim 9, wherein the insulating polymer comprises polystyrene, poly(α-methylstyrene), poly(methyl methacrylate), poly(vinyl phenol), poly(vinyl alcohol), poly(vinyl acetate), poly(vinyl chloride), poly(vinylidene fluoride), cycanoethylpullulan, or poly(divinyltetramethyldisiloxane-bis(benzocyclobutene)).

11. The composition of claim 6, wherein the organic solvent comprises (a) benzene that is unsubstituted or substituted with at least one alkyl group, (b) an alkane that is substituted with at least one halo group, (c) benzene that is substituted with at least one halo group, (d) a ketone, (e) an ether, (f) an amide, (g) an alkane, (h) or a mixture thereof.

12. A semiconductor device comprising a semiconductor layer comprising a small molecule semiconductor of Formula (I) 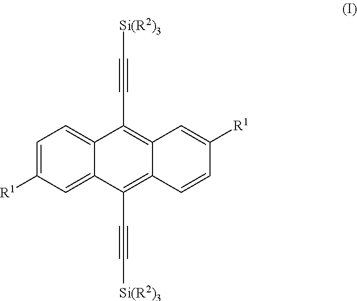
wherein
R¹ is a phenyl or naphthyl, wherein the phenyl or naphthyl is unsubstituted or substituted with one or more substituents selected from halogen, hydroxyl, amino, alkyl, alkenyl, alkoxy, acyloxy, heteroaryl, heteroalkyl, or heteroaralkyl; and
each R² is independently alkyl, alkenyl, alkoxy, aryl, heteroaryl, aralkyl, heteroalkyl, heteroaralkyl, or hydroxyalkyl.

13. The semiconductor device of claim 12, wherein the semiconductor layer further comprises an insulating polymer.

14. The semiconductor device of claim 12, further comprising a conducting layer, a dielectric layer, or a combination thereof adjacent to the semiconductor layer.

15. The semiconductor device of claim 12, further comprising a conducting layer adjacent to one surface of the semiconductor layer and a dielectric layer adjacent to an opposite surface of the semiconductor layer.

16. The semiconductor device of claim 12, further comprising an electrode layer comprising a source electrode and a drain electrode that are separated from each other and that are both in contact with the semiconductor layer.

17. The semiconductor device of claim 12, wherein the semiconductor device comprises an organic thin film transistor.

18. A method of making a semiconductor device, the method comprising:
providing a semiconductor layer comprising a small molecule semiconductor of Formula (I) 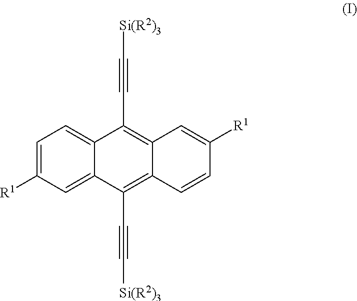
wherein
R¹ is a phenyl or naphthyl, wherein the phenyl or naphthyl is unsubstituted or substituted with one or more substituents selected from halogen, hydroxyl, amino, alkyl, alkenyl, alkoxy, acyloxy, heteroaryl, heteroalkyl, or heteroaralkyl; and
each R² is independently alkyl, alkenyl, alkoxy, aryl, heteroaryl, aralkyl, heteroalkyl, heteroaralkyl, or hydroxyalkyl.

19. The method of claim 18, wherein the semiconductor layer further comprises an insulating polymer.

20. The method of claim 18, further comprising providing a first layer adjacent to the semiconductor layer, the first layer comprising a conducting layer or a dielectric layer.

21. The method of claim 18, wherein the semiconductor device comprises an organic thin film transistor comprising multiple layers arranged in the following order:
a gate electrode;
a gate dielectric layer;
the semiconductor layer; and
an electrode layer comprising a source electrode and a drain electrode, wherein the source electrode and the drain electrode are separated from each other and wherein the semiconductor layer contacts both the drain electrode and the source electrode.

22. The method of claim 18, wherein the semiconductor device comprises an organic thin film transistor comprising multiple layers arranged in the following order:
a gate electrode;
a gate dielectric layer;
an electrode layer comprising a source electrode and a drain electrode, wherein the source electrode and the drain electrode are separated from each other; and
the semiconductor layer in contact with both the source electrode and the drain electrode.

23. The method of claim 18, wherein providing the semiconductor layer comprises applying a composition to a surface of another layer of the semiconductor device, the composition comprising the small molecule semiconductor of Formula (I) and an organic solvent that dissolves at least a portion of the small molecule semiconductor.

24. The method of claim 23, the method further comprising removing at least a portion of the organic solvent after applying the composition.
